(19) United States
(12) Patent Application Publication
(10) Pub. No.: US 2011/0011628 A1
(43) Pub. Date: Jan. 20, 2011

(54) HIGHLY THERMAL CONDUCTIVE CIRCUIT BOARD

(75) Inventors: Ming-Chi Kan, Tainan County (TW); Shao-Chung Hu, Taipei County (TW); Chien-Min Sung, Taipei County (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: KINIK COMPANY, Taipei (TW)

(21) Appl. No.: 12/643,045

(22) Filed: Dec. 21, 2009

(30) Foreign Application Priority Data
Jul. 17, 2009 (TW) 098124331

(51) Int. Cl. H05K 7/20

(52) U.S. Cl. 174/252

(57) ABSTRACT

A highly thermal conductive circuit board includes a composite substrate, and a metal layer, an insulating layer, and a conductor layer sequentially disposed on the composite substrate. When at least one electronic element is electrically disposed on the conductor layer of the highly thermal conductive circuit board, heat produced by the electronic element in operation is rapidly dissipated through characteristics such as a high thermal conductivity and a low thermal expansion coefficient of the highly thermal conductive circuit board.

### CROSS-REFERENCE TO RELATED APPLICATIONS

This non-provisional application claims priority under 35 U.S.C. §119(a) on Patent Application No(s). 098124331 filed in Taiwan, R.O.C. on Jul. 17, 2009, the entire contents of which are hereby incorporated by reference.

### BACKGROUND OF THE INVENTION

1. Field of Invention

The present invention relates to a circuit board and, more particularly, to a highly thermal conductive circuit board.

2. Related Art

With the rapid development of electronic technology, electronic products, such as cell phones, personal digital assistants (PDAs), handheld game consoles, and light emitting diode (LED) illumination equipments, currently develop towards high speed and light weight. However, as the volume of the electronic products is significantly reduced, and the operating speed of electronic elements in the electronic products is gradually increased, the problem of high heat dissipation resulting from various electronic elements occurs. If the heat fails to be dissipated in time, the operating speed of the electronic elements is reduced, and the electronic elements as well as the circuit (carrier) board for carrying the electronic elements may even get burnt or short-circuited.

Meanwhile, in order to make the electronic products lighter, the space that can be used inside the electronic products is relatively reduced, so that the heat produced by the circuit board and the electronic elements disposed in such an electronic product may only be dissipated through thermal conduction and natural convection. Generally, regarding the circuit board used in the electronic product, an insulating layer is mainly formed on a metal substrate, and a circuit layer is disposed on the insulating layer for the electronic elements to be electrically disposed thereon, for example, capacitors, resistors, LEDs, transistors, or other electronic elements are electrically disposed on the circuit layer. When the electronic elements start to operate, the heat produced thereby is sequentially conducted to the insulating layer and the metal substrate through the circuit layer, and dissipated by the insulating layer and the metal substrate, so as to reduce the temperature of the electronic elements. In order to further enhance the thermal conductive performance of the circuit board, a heat dissipation device such as a radiator or heat sink is usually additionally disposed on the other side of the metal substrate relative to the insulating layer, so as to dissipate the heat of the metal substrate to the air, thereby increasing the heat dissipation rate.

However, according to the above configuration of the circuit board, as thermal conductivities of the metal substrate and the insulating material are low, the heat is non-uniformly distributed on the circuit board, and is concentrated at positions disposed with the electronic elements to form hot spots, so that the electronic elements and the circuit board may easily get burnt. Meanwhile, the metal substrate, characterized in having a highly thermal expansion coefficient, may easily be deformed under thermal stress when heated, and thus the electronic elements disposed on the circuit board may fail.

Therefore, in the current manufacturing of the circuit board, a composite substrate is adapted to replace the metal substrate, for example, a composite substrate composed of reinforcing fiber and matrix resin, polymer, or metal. Due to characteristics of various composing materials, the thermal conductivity of the circuit board is enhanced, while the thermal expansibility thereof is reduced. Though the circuit board formed by the composite substrate effectively improves the heat dissipation efficiency of the electronic elements on the circuit board, the effect is limited. The reason is that, the surfaces of the composite substrate usually have many uneven micropores, and thus the insulating layer and the heat dissipation device, disposed on two opposite surfaces of the composite substrate, cannot be completely attached to the composite substrate. The micropores exist between the insulating layer and the composite substrate or between the heat dissipation device and the composite substrate may hinder the heat transfer, so that the heat produced by the electronic elements cannot be uniformly and rapidly conducted from the insulating layer to the composite substrate, distributed to other areas on the composite substrate, or accelerated into the air through the heat dissipation device. Thereby, the problems that the heat is non-uniformly distributed on the circuit board and the heat dissipation efficiency is low still exist.

### SUMMARY OF THE INVENTION

Accordingly, the present invention is a highly thermal conductive circuit board, adapted to solve the problem in the prior art that due to the low thermal conductivity of the conventional circuit board and the rough surfaces of the applied substrate, gaps are formed between the insulating layer and the surface of the substrate, which hinder the thermal conduction between the insulating layer and the substrate, and thus heat cannot be rapidly and uniformly conducted from the insulating layer to the substrate, thereby reducing the overall thermal conduction efficiency of the circuit board.

The present invention provides a highly thermal conductive circuit board for at least one electronic element to be electrically disposed thereon. The circuit board comprises a composite substrate, at least one metal layer, an insulating layer, and a conductor layer. The composite substrate has two opposite surfaces, and the metal layer is disposed on at least one of the two surfaces. The insulating layer and the conductor layer are sequentially disposed on the metal layer. The electronic element is electrically disposed on the conductor layer.

In the highly thermal conductive circuit board provided by the present invention, a metal layer is joined to and covered on the surface of the composite substrate, so as to effectively reduce the roughness of the surface of the composite substrate, and provide a flat contact surface between the composite substrate and the insulating layer, thereby greatly improving the thermal conduction efficiency between the composite substrate and the insulating layer.

Meanwhile, due to the disposition of the metal layer, the heat dissipation device is flatly attached to the highly thermal conductive circuit board, and dissipates the heat distributed on the highly thermal conductive circuit board to the air, thereby increasing the heat dissipation rate of the highly thermal conductive circuit board and the electronic element.

### BRIEF DESCRIPTION OF THE DRAWINGS

The present invention will become more fully understood from the detailed description given herein below for illustration only, and thus are not limitative of the present invention, and wherein:

FIG. 1 is a schematic structural view of a first embodiment of the present invention;

FIG. 2 is a schematic structural view of a second embodiment of the present invention;

FIG. 3 is a schematic structural view of the second embodiment of the present invention, in which a heat dissipation device is disposed;

FIG. 4 is a schematic structural view of the second embodiment of the present invention, in which anode metal layers are provided; and

FIG. 5 is a schematic structural view of the second embodiment of the present invention, in which a bi-layer conductor layer is provided.

### DETAILED DESCRIPTION OF THE INVENTION

The highly thermal conductive circuit board provided by the present invention is applied for at least one electronic element to be disposed thereon. The electronic element may be an LED, a laser diode (LD), a transistor, a resistor, a capacitor, or any other electronic element that produces high heat in operation as compared to its surrounding areas. The heat produced by the electronic element is rapidly conducted to other areas of the circuit board by using the highly thermal conductivity of the circuit board. Thereby, the heat is uniformly distributed on the circuit board, and is dissipated to the air through the circuit board, so that the heat dissipation rate is increased, and the temperature of the circuit board is effectively lowered.

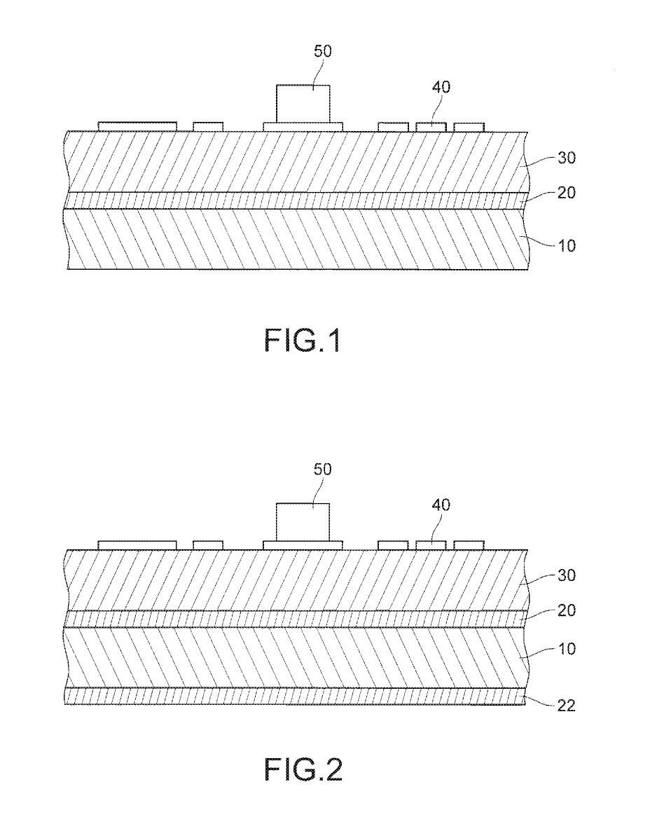

FIG. 1 shows a highly thermal conductive circuit board according to a first embodiment of the present invention. The circuit board comprises a composite substrate 10, a first metal layer 20, an insulating layer 30, and a conductor layer 40. The composite substrate 10 has two opposite surfaces, and is formed by a metal composite material composed of copper or aluminum and diamond, graphite, carbon fiber, or silicon carbide. In this embodiment, for ease of illustration, the composite substrate 10 is, for example but not limited to, an aluminum-base composite substrate composed of a diamond aluminum composite material, a graphite aluminum composite material, a carbon fiber aluminum composite material, or a silicon carbide aluminum composite material.

Generally, uneven micropores (not shown) exist on the surfaces of the composite substrate 10, so that the composite substrate 10 has two rough surfaces, which affects the heat dissipation efficiency of the composite substrate 10. Therefore, a metal material such as copper, nickel, or aluminum is joined by hot-pressing and completely covered on one of the two surfaces (an upper and a lower surface) of the composite substrate 10, or simultaneously joined to and covered on the upper and lower surfaces. In this embodiment, the metal material is joined to the upper surface of the composite substrate 10, so that a flat first metal layer 20 having a thickness in a range of 0.01 mm to 1 mm is formed on the upper surface of the composite substrate 10. Thus, the metal material is filled in the micropores on the composite substrate 10, so as to prevent the rough surfaces of the composite substrate 10 from affecting the thermal conduction efficiency of the composite substrate 10. Preferably, a thickness of the first metal layer 20 of the present invention is in a range of 0.03 mm to 0.5 mm.

Next, an insulating layer 30 is disposed on the first metal layer 20, and a composing material of the insulating layer 30 is selected from a group consisting of diamond, diamond-like carbon (DLC), epoxy resin, and any mixture thereof. As the diamond or DLC has a thermal conductivity of 400 to 600 Watts per meter-Kelvin (W/mk), and has a desirable insulating property, the thermal conduction efficiency of the insulating layer 30 is further enhanced when the insulating layer 30 contains the diamond or DLC. Moreover, before the insulating layer 30 is disposed on the first metal layer 20, an anode surface treatment is performed on the first metal layer 20 to form an anode metal layer on the first metal layer 20 (not shown), so as to improve the abrasion resistance and corrosion resistance of the composite substrate 10 in the subsequent process and the attachment of the first metal layer 20 to the insulating layer 30.

After the insulating layer 30 is disposed on the first metal layer 20, a conductor layer 40 is disposed on the insulating layer 30, and a composing material of the conductor layer 40 is selected from a group consisting of copper, nickel, gold, silver, beryllium, tin, and any alloy thereof. An electronic element 50 is disposed on the conductor layer 40, and electrically connected to the conductor layer 40.

The highly thermal conductive circuit board provided in the first embodiment of the present invention has an overall thermal conductivity of 400-650 W/mk. Due to the highly thermal conductivity of the circuit board, the heat produced by the electronic element 50 electrically disposed on the highly thermal conductive circuit board in operation is rapidly conducted and dissipated laterally and longitudinally from the position of the electronic element 50 on the circuit board to other positions on the circuit board through the highly thermal conductivities of the insulating layer 30, the first metal layer 20, and the composite substrate 10. In this manner, the heat is uniformly distributed on the highly thermal conductive circuit board, and dissipated to the air through heat exchange between the circuit board and the air, so as to maintain an operating temperature of the electronic element 50, and reduce the temperature of the highly thermal conductive circuit board, thereby preventing the circuit board from being burnt due to over-heated portions. Meanwhile, the highly thermal conductive circuit board has a thermal expansion coefficient lower than 10 ppm/K, so that the highly thermal conductive circuit board is prevented from being deformed under thermal stress as the working temperature of the highly thermal conductive circuit board gets too high.

FIG. 2 is a schematic structural view of a second embodiment of the present invention. The second embodiment of the present invention is substantially the same as the first embodiment in structure, but has the following differences. The highly thermal conductive circuit board provided in the second embodiment of the present invention comprises a composite substrate 10, a first metal layer 20, a second metal layer 22, an insulating layer 30, and a conductor layer 40. In the second embodiment, the composite substrate 10 is an aluminum-base composite substrate, for example, a diamond aluminum composite substrate, a graphite aluminum composite substrate, a carbon fiber aluminum composite substrate, or a silicon carbide aluminum composite substrate, and has two opposite surfaces. The first metal layer 20 and the second metal layer 22 are formed by a metal material such as aluminum, copper, or nickel, and are respectively disposed on the two surfaces of the composite substrate 10 by means of electroplating, hot-pressing, or infiltration. Thereby, the metal material is filled in the micropores on the two surfaces of the composite substrate 10, and the composite substrate 10 is entirely wrapped by the first metal layer 20 and the second metal layer 22, so as to achieve a desired flatness.

For example, when aluminum (having a thermal conductivity of 237 W/mk) is used as the composing material of the first and second metal layers 20, 22, the flat first metal layer 20 and second metal layer 22 are respectively formed on the two surfaces of the composite substrate 10 by means of electroplating, hot-pressing, or infiltration, thereby significantly reducing the roughness of the surfaces of the composite substrate 10.

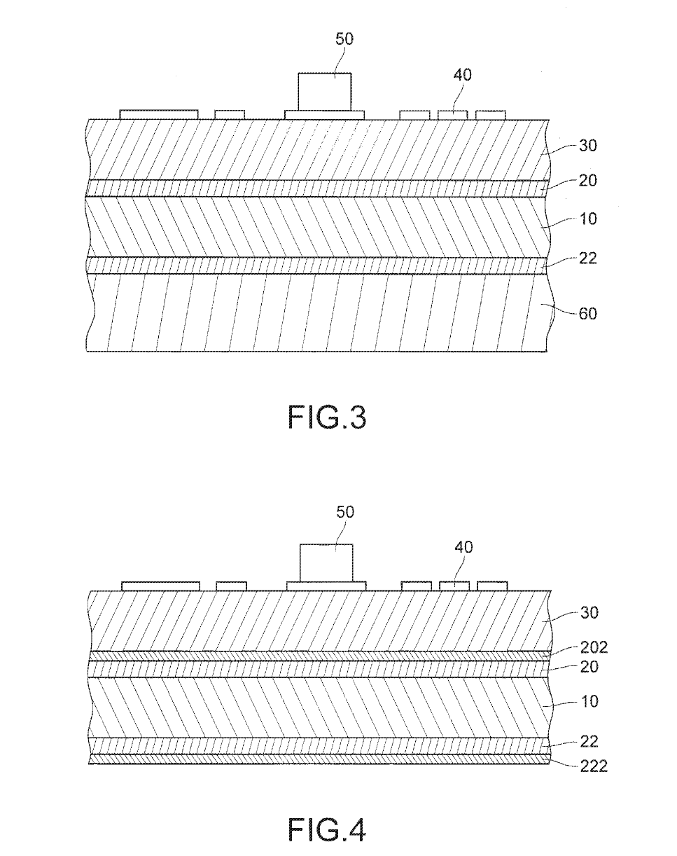

Afterward, an insulating layer 30 formed by diamond or DLC and a conductor layer 40 are sequentially disposed on the first metal layer 20 to complete the highly thermal conductive circuit board, and an electronic element 50 is electrically disposed on the conductor layer 40. Referring to FIG. 3, when the highly thermal conductive circuit board is used, in order to further enhance the heat dissipation efficiency of the electronic element 50, a heat dissipation device 60 such as a radiator or a heat sink (fin) is disposed on the second metal layer 22 of the highly thermal conductive circuit board at a position corresponding to that of the electronic element 50, so as to increase the heat exchange rate between the circuit board and the air. At this time, as the heat dissipation device 60 is flatly attached to the second metal layer 22, the heat distributed on the composite substrate 10 is uniformly conducted from the second metal layer 22 to the heat dissipation device 60, thereby reducing the temperature of the electronic element 50 and maintaining the operating temperature range thereof.

Further, referring to FIG. 4, when the first metal layer 20 and the second metal layer 22 are formed on the two surfaces of the composite substrate 10, an anode surface treatment is performed on the first metal layer 20 and the second metal layer 22 to respectively form a first anode metal layer 202 and a second anode metal layer 222, for example, anode aluminum layers, on the first metal layer 20 and the second metal layer 22. Thereby, the insulating property of the highly thermal conductive circuit board is further enhanced due to the configuration of the first anode metal layer 202 and the second anode metal layer 222.

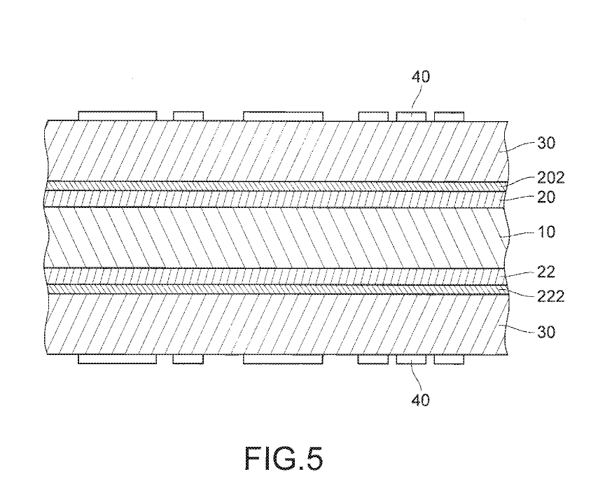

Referring to FIG. 5, in the highly thermal conductive circuit board provided in the second embodiment of the present invention, as the first metal layer 20 and the second metal layer 22 are respectively disposed on the two surfaces of the composite substrate 10, the composite substrate 10 has two flat contact surfaces. Therefore, after the first metal layer 20 and the second metal layer 22 are selectively anodized to form the first anode metal layer 202 and the second anode metal layer 222, in the subsequent process, the insulating layer 30 and the conductor layer 40 are sequentially disposed on the first anode metal layer 202 and the second anode metal layer 222 respectively depending on actual requirements of the highly thermal conductive circuit board in use, so as to form a highly thermal conductive circuit board having a bi-layer conductor layer 40.

In the highly thermal conductive circuit board of the present invention, a metal layer is disposed on at least one surface of the composite substrate, so that the surface of the composite substrate is flattened through the metal layer, thereby preventing the micropores originally disposed on the surface of the composite substrate from affecting the thermal conductive performance between the composite substrate and the insulating layer. Meanwhile, due to the joining of the composite substrate, the metal layer, and the insulating layer, the highly thermal conductive circuit board achieves the characteristics of a high thermal conductivity and a low thermal expansion coefficient. Therefore, the heat produced by the electronic element is rapidly transferred by the highly thermal conductive circuit board and distributed on the whole circuit board, and finally dissipated to the air through heat exchange between the circuit board and the air. In this manner, the highly thermal conductive circuit board may not be burnt due to some over-heated portions, and the electronic element remains to operate under its working temperature.

In addition, in the highly thermal conductive circuit board, when the two surfaces of the composite substrate are both wrapped with a metal layer, two flat surfaces are provided by the metal layers, and thus the heat dissipation device can be flatly attached to the highly thermal conductive circuit board. Therefore, the thermal conduction between the highly thermal conductive circuit board and the heat dissipation device is uniformly performed, and the heat conduction from the highly thermal conductive circuit board to the heat dissipation device is accelerated, thereby reducing the temperature of the highly thermal conductive circuit board as well as the operating temperature of the electronic element.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A highly thermal conductive circuit board, for at least one electronic element to be electrically disposed thereon, the circuit board comprising:
a composite substrate, having two opposite surfaces;
at least one metal layer, disposed on at least one of the surfaces of the composite substrate;
an insulating layer, disposed on the metal layer; and
a conductor layer, disposed on the insulating layer, wherein the electronic element is electrically disposed on the conductor layer.

2. The highly thermal conductive circuit board according to claim 1, wherein the composite substrate is an aluminum-base composite substrate.

3. The highly thermal conductive circuit board according to claim 2, wherein a composing material of the aluminum-base composite substrate is selected from a group consisting of a diamond aluminum composite material, a graphite aluminum composite material, a carbon fiber aluminum composite material, and a silicon carbide aluminum composite material.

4. The highly thermal conductive circuit board according to claim 1, wherein a composing material of the metal layer is selected from a group consisting of aluminum, copper, and nickel.

5. The highly thermal conductive circuit board according to claim 1, further comprising an anode metal layer, disposed between the metal layer and the insulating layer.

6. The highly thermal conductive circuit board according to claim 5, wherein the anode metal layer is an anode aluminum layer.

7. The highly thermal conductive circuit board according to claim 1, wherein a thickness of the metal layer is in a range of 0.01 mm to 1 mm.

8. The highly thermal conductive circuit board according to claim 7, wherein a thickness of the metal layer is in a range of 0.03 mm to 0.5 mm.

9. The highly thermal conductive circuit board according to claim 1, further comprising two metal layers, respectively disposed on the two surfaces of the composite substrate.

10. The highly thermal conductive circuit board according to claim 1, wherein a composing material of the insulating layer is selected from a group consisting of diamond, diamond-like carbon (DLC), epoxy resin, and any mixture thereof.

11. The highly thermal conductive circuit board according to claim 1, wherein a material of the conductor layer is selected from a group consisting of copper, nickel, gold, silver, beryllium, tin, and any alloy thereof.

12. The highly thermal conductive circuit board according to claim 1, wherein the metal layer is joined to the surface of the composite substrate through electroplating, hot-pressing, or infiltration.
